(19) United States
(12) Patent Application Publication
(10) Pub. No.: US 2023/0085370 A1
(43) Pub. Date: Mar. 16, 2023

(54) METHOD OF MANUFACTURING NON-CLASSICAL LIGHT SOURCE DEVICE, NON-CLASSICAL LIGHT SOURCE DEVICE, SINGLE-PHOTON SOURCE DEVICE, AND RANDOM NUMBER GENERATOR

(71) Applicant: NICHIA CORPORATION, Anan-shi (JP)

(72) Inventors: Tadashi KAWAZOE, Atsugi-shi (JP); Takuya KADOWAKI, Yokohama-shi (JP)

(73) Assignee: NICHIA CORPORATION, Anan-shi (JP)

(21) Appl. No.: 17/940,406

(22) Filed: Sep. 8, 2022

(30) Foreign Application Priority Data
Sep. 10, 2021 (JP) 2021-147963

(51) Int. Cl. H01L 33/00; H01L 33/58; H01L 33/06; H01L 27/15; G06F 7/58

(52) U.S. Cl. CPC H01L 33/0095; H01L 33/58; H01L 33/06; H01L 27/156; G06F 7/588; G06N 10/40

(57) ABSTRACT

A method of manufacturing a non-classical light source device includes: providing a semiconductor structure that includes a first semiconductor region having a first impurity of a first conductivity type that is one of p-type or n-type, and a second semiconductor region having a second impurity of a second conductivity type that is the other of p-type or n-type; and irradiating the semiconductor structure with laser light in the presence of a forward current flowing through the semiconductor structure while the semiconductor structure is in thermal contact with a cooling base at a temperature higher than −40° C. and lower than 15° C., thereby diffusing the second impurity.

### CROSS REFERENCE TO RELATED APPLICATION

This application claims priority to Japanese Patent Application No. 2021-147963, filed on Sep. 10, 2021, the disclosure of which is hereby incorporated by reference in its entirety.

### BACKGROUND

The present disclosure relates to a method of manufacturing a non-classical light source device, a non-classical light source device, a single-photon source device, and a random number generator.

In recent years, non-classical light, which cannot be described as classical electromagnetic fields, have been receiving attention in both basic and application fields. For example, Japanese Patent Publication No. 2017-195364 discloses a single-photon source that uses quantum dots to emit a single photon that is an example of non-classical light. Application of the single-photon source to, for example, quantum cryptographic communication has been expected. If a non-classical light source device is realized that is adapted to emit non-classical light even with a simple configuration, it will be helpful for practical use of a device that uses non-classical light.

In this specification, M. Ohtsu and T. Kawazoe, “Principles and Practices of Si Light Emitting Diodes using Dressed Photons” Off-shell archive, Off Shell: 1805R.001.v1., (2018) is also incorporated by reference in its entirety.

### SUMMARY

A non-classical light source device that is adapted to emit non-classical light even with a simple configuration and a method of manufacturing the non-classical light source device are desired.

According to one embodiment of the present disclosure, a method of manufacturing a non-classical light source device includes: providing a semiconductor structure, the semiconductor structure including a first semiconductor region having a first impurity of a first conductivity type that is one of p-type and n-type and a second semiconductor region having a second impurity of a second conductivity type that is the other of p-type and n-type; and irradiating the semiconductor structure with light in the presence of a forward current flowing through the semiconductor structure while the semiconductor structure is in thermal contact with a cooling base at a temperature higher than −40° C. and lower than 15° C., thereby diffusing the second impurity.

According to another embodiment of the present disclosure, a non-classical light source device includes: a semiconductor structure, the semiconductor structure including a first semiconductor region having a conductivity type that is one of p-type and n-type, a second semiconductor region having a conductivity type that is the other of p-type and n-type, a pn junction located between the first semiconductor region and the second semiconductor region, and a plurality of light-emitting regions discretely distributed along the pn junction, each of the light-emitting regions being adapted to emit non-classical light; and an electrode structure for applying a voltage to the pn junction, wherein a principal material of the first semiconductor region and the second semiconductor region is made of an indirect bandgap semiconductor, and as viewed using a camera with the spatial resolution of 10 μm at a predetermined frame rate in a direction perpendicular to the pn junction, portions of light respectively emitted from the plurality of light-emitting regions are observed as being separated from one another.

According to certain embodiments of the present disclosure, a non-classical light source device that is adapted to emit non-classical light even with a simple configuration and a method of manufacturing the non-classical light source device can be realized.

### BRIEF DESCRIPTION OF THE DRAWINGS

FIG. 1 is a perspective view schematically showing a configuration of a non-classical light source device according to an example embodiment.

FIG. 2 is a cross-sectional view of the second semiconductor region taken along the dashed line shown in FIG. 1.

FIG. 3 is a graph schematically illustrating the current-voltage characteristic of a semiconductor structure of the present embodiment.

FIG. 4A is a diagram for illustrating an example of a step of a method of manufacturing a non-classical light source device according to the present embodiment.

FIG. 4B is a diagram for illustrating an example of a step of a method of manufacturing a non-classical light source device according to the present embodiment.

FIG. 4C is a diagram for illustrating an example of a step of a method of manufacturing a non-classical light source device according to the present embodiment.

FIG. 4D is a diagram for illustrating an example of a step of a method of manufacturing a non-classical light source device according to the present embodiment.

FIG. 4E is a diagram for illustrating an example of a step of a method of manufacturing a non-classical light source device according to the present embodiment.

FIG. 4F is a diagram for illustrating a variation example of a step of a method of manufacturing a non-classical light source device according to the present embodiment.

FIG. 5A is a diagram schematically showing a configuration of a single-photon source device according to an example embodiment.

FIG. 5B is a diagram schematically showing a configuration of a quantum cryptographic communication device according to an example embodiment.

FIG. 5C is a diagram schematically showing a configuration of an optical coherence tomograph according to an example embodiment.

FIG. 5D is a diagram schematically showing a configuration of a random number generator according to an example embodiment.

FIG. 5E is a diagram schematically showing another configuration of a random number generator according to an example embodiment.

FIG. 6 is a photographic image of the upper surface of a non-classical light source device of Example 1.

FIG. 7A is a photographic image of emission of light from the non-classical light source device of Example 1.

FIG. 7B is a photographic image of emission of light from a light source device of Comparative Example 1.

FIG. 8A is a graph showing the relationship between the intensity of light emitted from the non-classical light source device of Example 1 and the time.

FIG. 8B is a graph showing the relationship between the intensity of light emitted with periods of 1.1 ns (pulse frequency: 900 MHz) from the non-classical light source device of Example 1 and the time.

FIG. 8C is a graph showing the relationship between the intensity of light emitted from the light source device of Comparative Example 1 and the time.

FIG. 9 is a graph showing the current-voltage characteristic of a semiconductor structure of Example 1.

FIG. 10 is a diagram schematically showing a Hanbury Brown-Twiss experimental system for measurement of the intensity correlation.

FIG. 11A is a graph schematically showing the intensity correlation function in a continuous wave.

FIG. 11B is a graph schematically showing the intensity correlation function in periodically pulsed light.

FIG. 12 is a graph of the intensity correlation function of light emitted with periods of 1.1 nanoseconds (pulse frequency: 900 MHz) from the non-classical light source device of Example 1.

### DETAILED DESCRIPTION

Hereinafter, with reference to the drawings, a non-classical light source device and a method of manufacturing the non-classical light source device according to embodiments of the present disclosure are described in detail. The same reference characters in a plurality of drawings denote the same or similar parts.

The description below is intended to give a concrete form to the technical ideas of the present invention, but the scope of the present invention is not intended to be limited thereto. The size, material, shape, relative arrangement, etc., of the components are intended as examples, and the scope of the present invention is not intended to be limited thereto. The size, arrangement relationship, etc., of the members shown in each drawing may be exaggerated in order to facilitate understanding.

Where there is more than one of the same component, they may be prefixed with “first” and “second” in order to distinguish them from one another in the present specification or the claims. Where the manner in which the distinction is made in the present specification is different from that in the claims, the same prefix may not refer to the same member in the present specification and in the claims.

### EMBODIMENT

<Non-Classical Light Source Device>

A non-classical light source device according to an embodiment of the present disclosure includes: a semiconductor structure, the semiconductor structure including a first semiconductor region having a conductivity type that is one of p-type and n-type, a second semiconductor region having a conductivity type that is the other of p-type and n-type, a pn junction located between the first semiconductor region and the second semiconductor region, and a plurality of light-emitting regions discretely distributed along the pn junction, each of the light-emitting regions being adapted to emit non-classical light; and an electrode structure for applying a voltage to the pn junction, wherein a principal material of the first semiconductor region and the second semiconductor region is made of an indirect bandgap semiconductor, and as viewed using a camera with the spatial resolution of 10 μm at a predetermined frame rate in a direction perpendicular to the pn junction, portions of light respectively emitted from the plurality of light-emitting regions are observed as being separated from one another.

According to such a non-classical light source device, non-classical light can be emitted even with a simple configuration. The non-classical light refers to light whose intensity correlation function g⁽²⁾(τ) satisfies the relationship of g⁽²⁾(0)<g⁽²⁾(τ) (τ≠0) and that represents antibunching of photons. Note that the intensity correlation function g⁽²⁾(τ) represents the time correlation between two photons.

A non-classical light source device of the present embodiment includes a plurality of light-emitting regions. In each of the plurality of light-emitting regions, the light-emitting region utilizes dressed photons, which are one kind of near-field light, to emit non-classical light that includes a plurality of photons in the form of pulsed light at a certain pulse frequency. Dressed photons are considered to be virtual photons that represent a state of an interaction of electron-hole pairs in a semiconductor and photons. Dressed photons, which are virtual photons, can exist as dressed photon phonons via, for example, phonons that represent the lattice vibration in crystals, particularly via coherent phonons. When dressed photon phonons decay into photons and phonons, the momentum of the photons includes uncertainty of the phonons, which is almost as large as the momentum of the phonons. Therefore, even with an indirect bandgap semiconductor, the dressed photon phonons compensate for the difference in momentum between the highest energy of the valence band and the lowest energy of the conduction band so that light of a lower energy than the bandgap of the indirect bandgap semiconductor can be emitted.

Coherent phonons can stably exist in dopant pairs formed by impurities introduced into a semiconductor as dopants. Such dopant pairs can be formed by unusual annealing called dressed photon phonon-assisted annealing (hereinafter, referred to as “DPP annealing”). DPP annealing is a process of irradiating a semiconductor containing impurities with light at a predetermined peak wavelength in the presence of a forward current flowing through the semiconductor. Details of the DPP annealing will be described below.

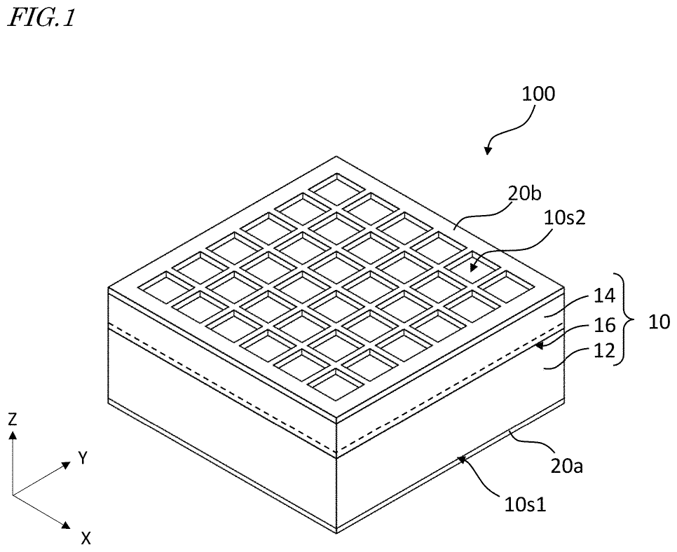

Hereinafter, a basic configuration example of a non-classical light source device according to an embodiment of the present disclosure is described with reference to FIG. 1. In the following description, for the sake of simplicity, the non-classical light source device is simply referred to as a “light source device.”

FIG. 1 is a perspective view schematically showing a configuration of a light source device 100 according to an example embodiment. In the drawing, for the sake of reference, X, Y and Z axes that are perpendicular to one another are schematically shown. The direction of the arrow of X axis is referred to as +X direction, and the direction opposite to +X direction is referred to as −X direction. When it is not necessary to distinguish between +X direction and −X direction, they are simply referred to as X direction. The same applies to Y axis and Z axis. In this specification, for the sake of clarity in description, +Z direction is referred to as “upper” and −Z direction is referred to as “lower.” A part located on the upper side is referred to as “upper part” and a part located on the lower side is referred to as “lower part.” This does not limit the orientation of the light source device 100 when used, but the light source device 100 can have an arbitrary orientation when used.

The light source device 100 shown in FIG. 1 includes a semiconductor structure 10, a lower electrode 20a, and an upper electrode 20b. Hereinafter, the configuration of the semiconductor structure 10, the lower electrode 20a, and the upper electrode 20b is described.

[Semiconductor Structure 10]

The semiconductor structure 10 includes a first semiconductor region 12 and a second semiconductor region 14, in which a principal material is an indirect bandgap semiconductor. The first semiconductor region 12 has a first impurity of a first conductivity type that is one of p-type and n-type. The second semiconductor region 14 has a second impurity of a second conductivity type that is the other of p-type and n-type. The semiconductor structure 10 includes a pn junction 16 located (at the interface) between the first semiconductor region 12 and the second semiconductor region 14. The pn junction 16 can be parallel to, for example, the XY plane. The semiconductor structure 10 has a rear surface 10s1 in the first semiconductor region 12 and a front surface 10s2 in the second semiconductor region 14. The rear surface 10s1 and the front surface 10s2 can be parallel to, for example, the XY plane.

[First Semiconductor Region 12]

The first semiconductor region 12 is made of an indirect semiconductor. The principal material of the first semiconductor region 12 can be, for example, at least one semiconductor selected from the group consisting of silicon (Si), germanium (Ge), silicon carbide (SiC), gallium phosphide (GaP) and diamond. A preferred principal material of the first semiconductor region 12 is Si. When the principal material is Si, the first semiconductor region 12 has as the first impurity at least one type of atom selected from the group consisting of phosphorus (P) atom, arsenic (As) atom, antimony (Sb) atom, boron (B) atom, and aluminum (Al) atom. When the first conductivity type is n-type, the first impurity is preferably As atom or Sb atom. The concentration of the first impurity is, for example, equal to or higher than 1.0×10¹⁴ cm⁻³ and equal to or lower than 1.0×10²⁰ cm⁻³. The first semiconductor region 12 may be a n-type silicon substrate or may include, in addition to the n-type silicon substrate, a n-type silicon semiconductor layer provided on the n-type silicon substrate.

[Second Semiconductor Region 14]

The second semiconductor region 14 is made of an indirect semiconductor. The principal material of the second semiconductor region 14 can be the same as the principal material of the first semiconductor region 12. The second impurity can have a concentration gradient in a direction perpendicular to the front surface 10s2. When the principal material of the first semiconductor region 12 is Si and the second conductivity type is p-type, the second impurity is preferably B atom or Al atom. The concentration distribution of the second impurity can have a peak at a certain depth from the front surface 10s2. The peak concentration of the second impurity in the depth direction can be, for example, equal to or higher than 1.0×10¹⁶ cm⁻³ and equal to or lower than 1.0×10²⁰ cm⁻³.

The concentration of the first and second impurities can be analyzed by, for example, Secondary Ion Mass Spectroscopy (SIMS) or three-dimensional atom probe.

Due to the high-concentration impurities near the front surface, the contact resistance with the upper electrode can be reduced.

[Lower Electrode 20a and Upper Electrode 20b]

The lower electrode 20a is provided on the rear surface 10s1, and the upper electrode 20b is provided on the front surface 10s2. Via the lower electrode 20a and the upper electrode 20b, a voltage is applied to the pn junction 16. In this specification, the lower electrode 20a and the upper electrode 20b are also together referred to as “electrode structure.” The upper electrode 20b has, for example, a plurality of through holes as light-transmitting regions. The plurality of through holes may be formed by, for example, forming the upper electrode 20b in the shape of a mesh. By applying a stationary DC voltage to the pn junction 16, non-classical light is produced inside the semiconductor structure 10, and the non-classical light goes out from the front surface 10s2 via the light-transmitting regions of the upper electrode 20b. The upper electrode 20b can be a single-layer or multilayer structure including at least one metal selected from the group consisting of copper (Cu), chromium (Cr), aluminum (Al), gold (Au), titanium (Ti) platinum (Pt) and silver (Ag). When the upper electrode 20b is a light-transmitting electrode, the upper electrode 20b does not need to have a plurality of through holes because the light-transmitting electrode itself has a light-transmitting region. The transmittance of the light-transmitting regions for the non-classical light can be, for example, equal to or higher than 60%, preferably 80%. In this case, the upper electrode 20b can be a light-transmitting electrode such as ITO.

Part of the non-classical light produced inside the semiconductor structure 10 that is traveling downward is reflected by the lower electrode 20a so as to travel upward. This can improve the extraction efficiency of the non-classical light. The lower electrode 20a can be a single-layer or multilayer structure including at least one metal selected from the group consisting of, for example, Cu, Cr, Al, Au, Ti, Pt and Ag.

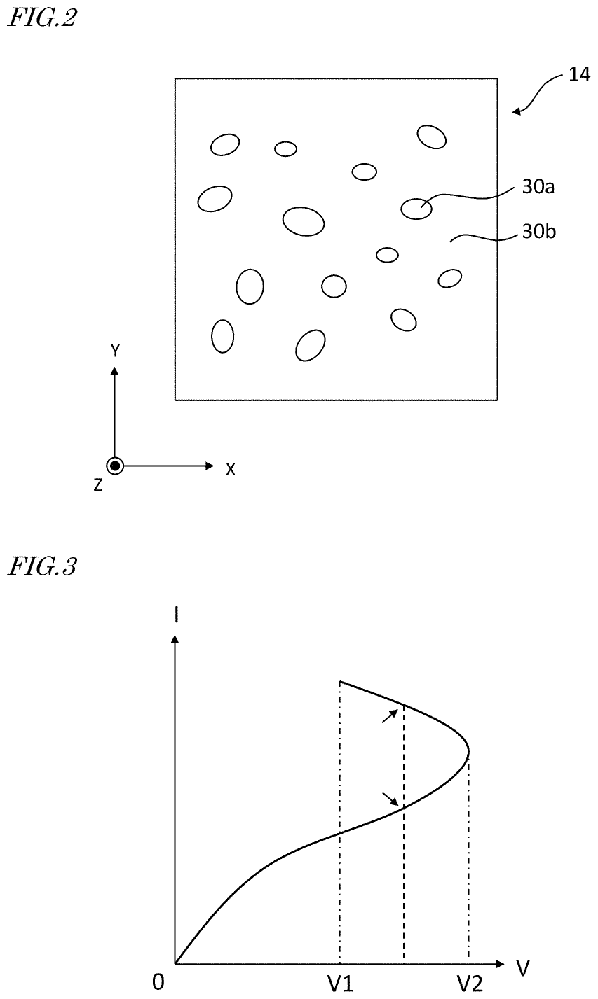

Next, the positions inside the semiconductor structure 10 where the non-classical light is caused are described with reference to FIG. 2. FIG. 2 is a cross-sectional view of the second semiconductor region 14 taken along the dashed line shown in FIG. 1. The cross-sectional plane extends along the pn junction 16 and is parallel to the XY plane. As shown in FIG. 2, the light source device 100 has, in the second semiconductor region 14, a plurality of light-emitting regions 30a whose dimensions are different from one another and a non light-emitting region 30b surrounding each of the light-emitting regions 30a. The plurality of light-emitting regions 30a are discretely distributed along the pn junction 16 shown in FIG. 1. In this specification, the phrase “the plurality of light-emitting regions 30a are discretely distributed” involves both a case in which the plurality of light-emitting regions 30a are regularly distributed with the non light-emitting region 30b interposed therebetween and a case in which the plurality of light-emitting regions 30a are irregularly distributed with the non light-emitting region 30b interposed therebetween. The plurality of light-emitting regions 30a are expected to be located near a depletion layer that is formed by the pn junction 16. Each of the light-emitting regions 30a is adapted to emit non-classical light that includes a plurality of photons in the form of light pulses at a certain pulse frequency. In actuality, each of the light-emitting regions 30a does not have a planar shape such as shown in FIG. 2 but has a three-dimensional shape. The extent in the XY plane of each light-emitting region 30a is relatively large, while the extent in the Z direction is relatively small. In this specification, the light-emitting regions are defined by regions in which the intensity of light is equal to or higher than 1/e² of the peak intensity. e is the base of the natural logarithm. Each of the light-emitting regions 30a shown in FIG. 2 has an elliptical shape, but in actuality can have a more complicated shape.

When viewed in a direction perpendicular to the pn junction 16, the area of each of the light-emitting regions 30a can be, for example, equal to or smaller than 25 μm². Each of the light-emitting regions 30a can be present inside, for example, an imaginary square of 5 μm on one side. When viewed using a camera with the spatial resolution of 10 μm at a predetermined frame rate in a direction perpendicular to the pn junction, portions of light respectively emitted from the plurality of light-emitting regions are observed as being separated from one another. The predetermined frame rate can be, for example, 16.7 milliseconds. When viewed in a direction perpendicular to the pn junction 16, the shortest distance between adjacent two of the plurality of light-emitting regions 30a can be, for example, equal to or greater than 10 μm. Preferably, the shortest distance between one light-emitting region 30a and an adjacent light-emitting region 30a that is closest to the one light-emitting region 30a can be, for example, equal to or greater than 10 μm. The shortest distance of equal to or greater than 10 μm between adjacent two of the plurality of light-emitting regions 30a may be verified by confirming that, as viewed using a camera with the spatial resolution of 10 μm at a predetermined frame rate in a direction perpendicular to the pn junction, portions of light respectively emitted from the plurality of light-emitting regions are observed as being separated from one another.

The principle according to which non-classical light including a plurality of photons is emitted from each of the light-emitting regions 30a can be estimated as follows. Each of the light-emitting regions 30a includes a plurality of dopant pairs. The dopant pairs are formed by pairs of the second impurity. The non light-emitting region 30b is a region that does not include such a dopant pair or a region that does not include a sufficient amount of dopant pairs to produce non-classical light. When a stationary forward voltage is applied to the pn junction 16 by the electrode structure, dressed photon phonons are produced in the dopant pairs. Accordingly, the light-emitting regions 30a can emit photons. When a photon is emitted from one of a plurality of dopant pairs included in one light-emitting region 30a, this photon stimulates other dopant pairs to emit photons. Due to such stimulated emission, a plurality of photons are synchronously emitted as non-classical light from the above-described light-emitting regions 30a. The synchronously-emitted photons have the same quantum state (e.g., polarized state). Therefore, each of the light-emitting regions 30a functions as a local oscillator that does not have a resonator structure. The light-emitting regions 30a that use dressed photon phonons for emission of light can be referred to as “near-field light formation region.”

Between at least two of the plurality of light-emitting regions 30a, the number of dopant pairs can be different. Therefore, the areas of the at least two light-emitting regions can be different. Due to the difference in the number of dopant pairs, the number of photons to be emitted from the at least two light-emitting regions can also be different. In other words, when one light-emitting region 30a behaves in a state such as defined by n photons, at least one of the other light-emitting regions 30a can behave in a state such as defined by m photons (n≠m). For example, when one light-emitting region 30a is in a photon number state of photon number n, |n>, the other light-emitting regions 30a can be in a photon number state of photon number m, |m>(n≠m). Alternatively, in one light-emitting region 30a, n single photons are produced from a plurality of dopant pairs included in the one light-emitting region 30a, while m single photons (n≠m) can be produced from at least one of the other light-emitting regions 30a. This can be estimated from the fact that, between at least two of the plurality of light-emitting regions 30a, the emission intensity at a predetermined cumulative time can be different. Adjacent two of the plurality of light-emitting regions 30a are distant from each other by a predetermined distance with the non light-emitting region 30b interposed therebetween. Therefore, dressed photon phonons produced in one of the adjacent two light-emitting regions 30a do not affect the other light-emitting region 30a, and a plurality of photons are emitted at independent timings.

The energy of each of the above-described photons depends on the energy of irradiation light in the DPP annealing. When the energy of the irradiation light in the DPP annealing is lower than the energy of the bandgap of the indirect bandgap semiconductor, the energy of each photon is lower than the energy of the bandgap of the indirect bandgap semiconductor. According to the conditions of the DPP annealing, the energy of each photon may be equal to, or may be different from, the energy of the irradiation light in the DPP annealing. The direction of polarization of each photon is equal to the direction of polarization of the irradiation light in the DPP annealing.

Next, the principle according to which non-classical light is emitted at a certain pulse frequency from each of the light-emitting regions 30a is described with reference to FIG. 3. FIG. 3 is a graph schematically illustrating the current-voltage characteristic of the semiconductor structure 10 of the present embodiment. Single dot chain lines represent voltage values V1 and V2, and a dashed line represents a voltage value between voltage values V1 and V2. The two arrows shown in FIG. 3 represent intersections of the current-voltage characteristic and the dashed line. As shown in FIG. 3, as the current I increases, the voltage V monotonically increases and then monotonically decreases. The semiconductor structure 10 exhibits such negative resistance that the correlation between the current I and the voltage V is negative.

Now, a stationary DC voltage is applied across the semiconductor structure 10 by the electrode structure. When the voltage V is equal to or higher than 0 and lower than V1, the current I represents a single value. When the voltage V is equal to or higher than V1 and lower than V2, the current I represents two values. When the voltage represented by the dashed line in FIG. 3 is applied, relaxation oscillation occurs such that the current I alternates between two values (see the arrows). It is estimated that this relaxation oscillation causes the light source device 100 to be periodically driven, and the non-classical light is emitted at a certain pulse frequency. After the non-classical light has been emitted, the current changes from a high value to a low value. Assuming that each of the light-emitting regions 30a has electrical resistance R and electrical capacitance C that are connected in series, the pulse frequency can be determined by f=1/(2πCR). The electrical resistance R reflects the negative resistance and, thus, the electrical resistance R before the emission of the light pulses and the electrical resistance R after the emission of the light pulses can be different. The electrical capacitance C is determined by the dimensions of each of the light-emitting regions 30a. The pulse frequency can be, for example, equal to or higher than 100 MHz and equal to or lower than 10 GHz. The pulse frequency of at least two of the plurality of light-emitting regions 30a can be different due to the difference in the dimensions of the light-emitting regions 30a.

As described above, the light source device 100 of the present embodiment, which has a simple configuration of the semiconductor structure 10 and the electrode structure, is adapted to emit from each of the plurality of light-emitting regions 30a non-classical light that includes a plurality of photons in the form of light pulses at a certain pulse frequency.

<Method of Manufacturing Non-Classical Light Source Device>

A method of manufacturing a non-classical light source device according to an embodiment of the present disclosure includes: providing a semiconductor structure, the semiconductor structure including a first semiconductor region having a first impurity of a first conductivity type that is one of p-type and n-type and a second semiconductor region having a second impurity of a second conductivity type that is the other of p-type and n-type; and irradiating the semiconductor structure with light in the presence of a forward current flowing through the semiconductor structure while the semiconductor structure is in thermal contact with a cooling base at a temperature higher than −40° C. and lower than 15° C., thereby diffusing the second impurity. Such a method of manufacturing a non-classical light source device enables manufacture of a non-classical light source device that is adapted to emit non-classical light even with a simple configuration.

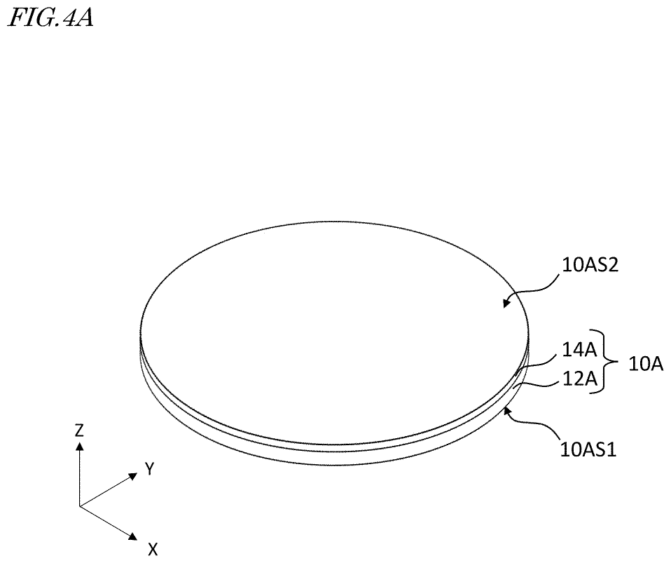

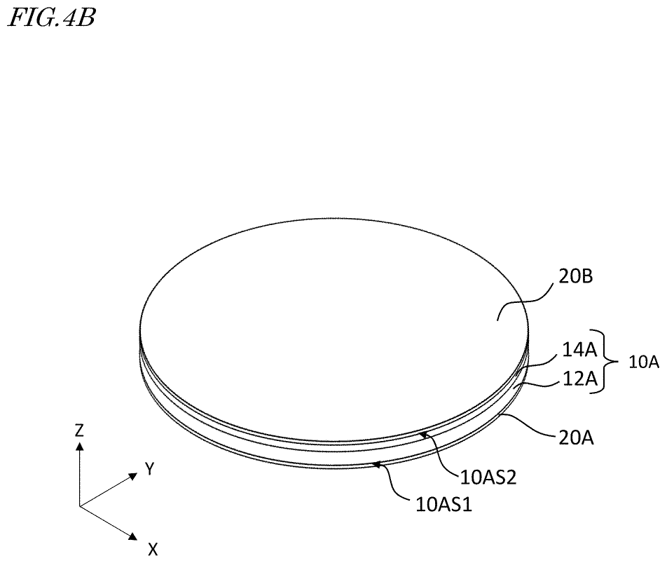

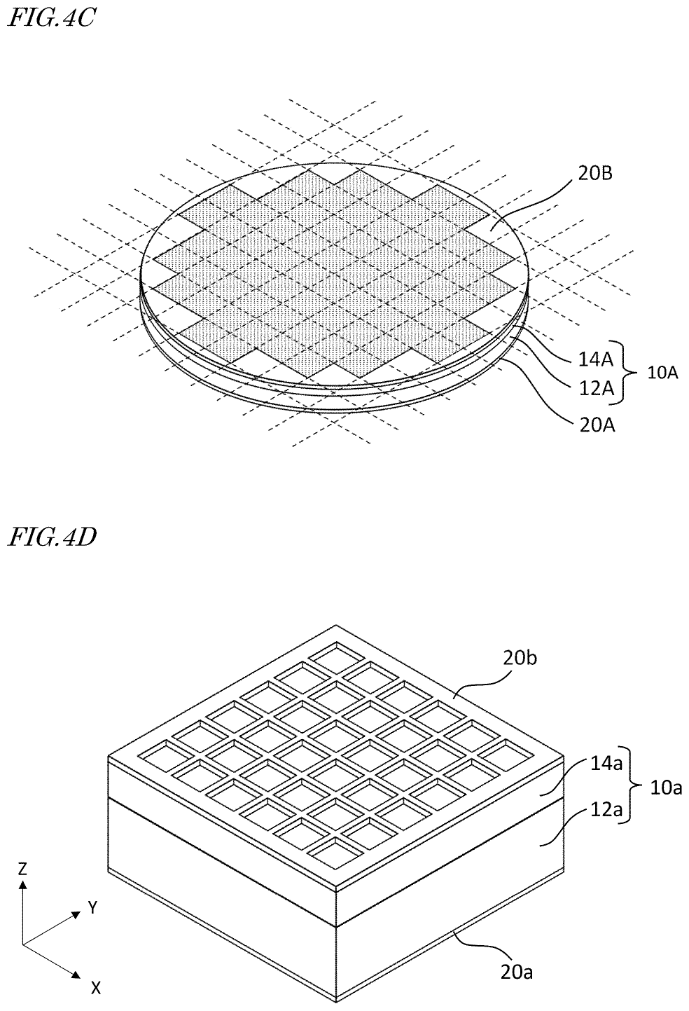

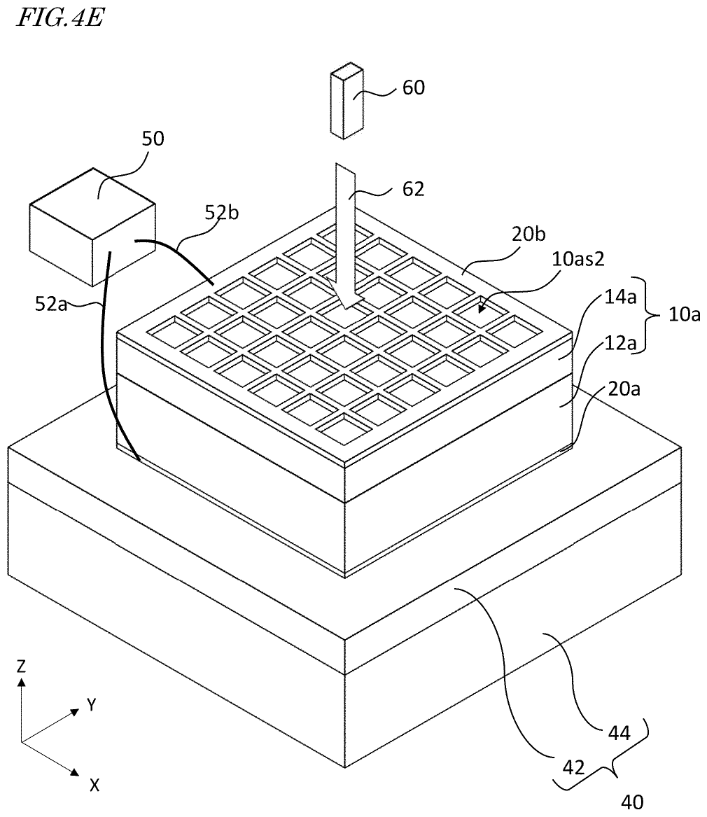

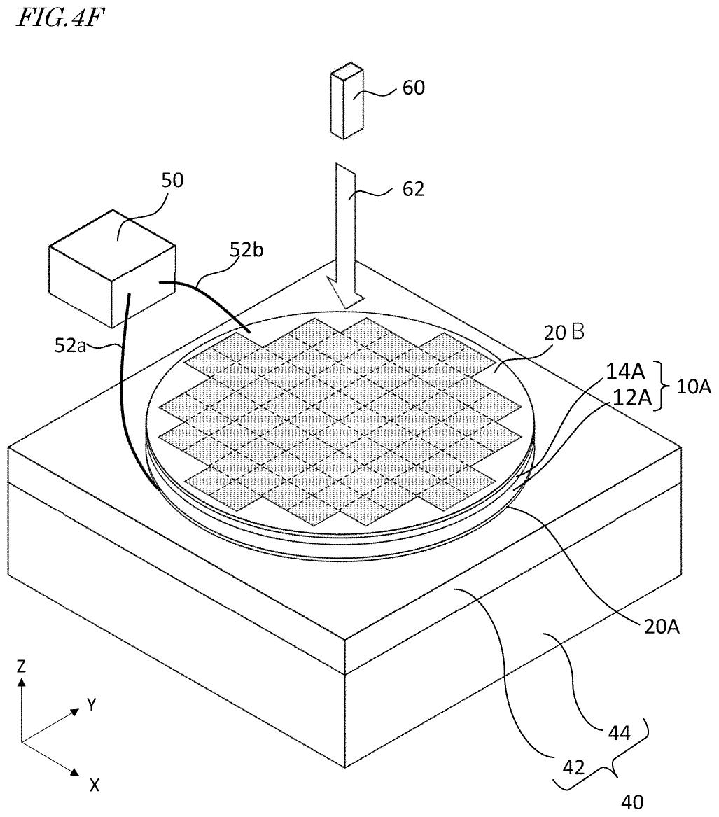

Hereinafter, a method of manufacturing a non-classical light source device according to an embodiment of the present disclosure is described with reference to FIG. 4A, FIG. 4B, FIG. 4C, FIG. 4D, FIG. 4E and FIG. 4F. FIG. 4A, FIG. 4B, FIG. 4C, FIG. 4D, FIG. 4E and FIG. 4F are diagrams for illustrating examples of steps of a method of manufacturing a non-classical light source device according to the present embodiment. According to the non-classical light source device method of manufacturing the present disclosure, a semiconductor wafer is divided into individual chips, whereby a plurality of non-classical light source devices can be manufactured. Thus, mass production of the non-classical light source device is possible.

[Step of Providing Semiconductor Structure 10A]

As shown in FIG. 4A, a semiconductor structure 10A in the form of a wafer is provided that includes a first semiconductor region 12A and a second semiconductor region 14A. The semiconductor structure 10A has a rear surface 10AS1 in the first semiconductor region 12A and a front surface 10AS2 in the second semiconductor region 14A. The first semiconductor region 12A has a first impurity of a first conductivity type that is one of p-type and n-type. The second semiconductor region 14A has a second impurity of a second conductivity type that is the other of p-type and n-type. In this step, the first impurity is activated, while the second impurity is not activated. The principal material of the first semiconductor region 12A and the second semiconductor region 14A is made of an indirect bandgap semiconductor. The principal material can be at least one semiconductor selected from the group consisting of, for example, Si, Ge, SiC, GaP and diamond. The dimension in the Z direction of the first semiconductor region 12A can be, for example, equal to or greater than 10 μm and equal to or smaller than 1000 μm. The dimension in the Z direction of the second semiconductor region 14A can be, for example, equal to or greater than 2 μm and equal to or smaller than 10 μm. Note that the semiconductor structure 10A may be in the form of a wafer as shown in FIG. 4A but is not limited to this example. For example, the semiconductor structure 10A may be in the form of an individual chip prepared beforehand by dividing.

The semiconductor structure 10A can be formed by the following two methods. The first method is ion implantation, into a semiconductor substrate that includes the first impurity of the first conductivity type that is one of p-type and n-type, of the second impurity of the second conductivity type that is the other of p-type and n-type. The ion-implanted portion of the semiconductor substrate is the second semiconductor region 14A, while the other portion is the first semiconductor region 12A. The second method includes forming a semiconductor layer of the first conductivity type by chemical vapor deposition on a semiconductor substrate that includes the first impurity of the first conductivity type that is one of p-type and n-type, and ion-implanting the second impurity of the second conductivity type that is the other of p-type and n-type into a surface of the semiconductor layer of the first conductivity type. The semiconductor substrate can be, for example, a semiconductor monocrystalline substrate, and the semiconductor layer can be, for example, an epitaxially-grown semiconductor layer. The ion-implanted portion of the semiconductor layer is the second semiconductor region 14A, while the other portion of the semiconductor layer and the entirety of the semiconductor substrate form the first semiconductor region 12A.

The distribution of the first impurity inside the first semiconductor region 12A is not particularly limited. However, as the distribution of the first impurity inside the first semiconductor region 12A is more uniform, the electrical resistivity of the first semiconductor region 12A can be lower. As a result, in the DPP annealing, the Joule heat produced in the first semiconductor region 12A can be suppressed to a low level, and heat radiation is easy. The concentration of the first impurity is, for example, equal to or higher than 1.0×10¹⁴ cm⁻³ and equal to or lower than 1.0×10²⁰ cm⁻³. When the principal material of the first semiconductor region is Si, the first impurity is at least one type of atom selected from the group consisting of, for example, P atom, As atom, Sb atom, B atom and Al atom. When the first conductivity type is n-type, the first impurity is preferably As atom or Sb atom. When the semiconductor structure 10A is formed by the first method, the first semiconductor region 12A is realized by the semiconductor substrate. In this case, the concentration of the first impurity included in the first semiconductor region 12A is preferably equal to or higher than 1.0×10¹⁴ cm⁻³ and equal to or lower than 1.0×10²⁰ cm⁻³. When the semiconductor structure 10A is formed by the second method, the first semiconductor region 12A includes, in addition to the semiconductor substrate, a semiconductor layer of the first conductivity type that is formed on the semiconductor substrate by chemical vapor deposition. In this case, it is preferred that the concentration of the first impurity included in the semiconductor substrate is equal to or higher than 1.0×10¹⁴ cm⁻³ and equal to or lower than 1.0×10²⁰ cm⁻³, and the concentration of the first impurity included in the semiconductor layer of the first semiconductor region 12A is equal to or higher than 1.0×10¹⁴ cm⁻³ and equal to or lower than 1.0×10²⁰ cm⁻³. More preferably, the concentration of the first impurity included in the semiconductor layer is equal to or higher than 1.0×10¹⁴ cm⁻³ and equal to or lower than 1.0×10¹⁶ cm⁻³.

The concentration of the impurity included in the semiconductor structure 10A can be estimated from, for example, the relationship between the impurity concentration and the electrical resistivity described in John. C. Irvin, “Resistivity of bulk silicon and of diffused layers in silicon” The Bell System Technical Journal, 41, 387 (1962).

The second impurity has a concentration gradient in the depth direction, and the concentration distribution of the second impurity can have a peak at a certain depth from the front surface. The peak concentration of the second impurity in the depth direction can be, for example, equal to or higher than 1.0×10¹⁶ cm⁻³ and equal to or lower than 1.0×10²⁰ cm⁻³. The concentration distribution of the second impurity may have, in some cases, a relatively high concentration in a region in a plane perpendicular to the depth direction and a relatively low concentration outside the relatively-high concentration region. When the principal material of the first semiconductor region is Si, the second impurity is, for example, any atom selected from P atom, As atom, Sb atom, B atom and Al atom that is capable of forming the second semiconductor region of the second conductivity type that is different from the first conductivity type. When the second conductivity type is p-type, the second impurity is preferably B atom or Al atom. When the atom of the second impurity is lighter in weight than the atom of the first impurity, the second impurity can be diffused by the DPP annealing that will be described later, and a light-emitting region 30a can be formed of a group of dopant pairs.

[Step of Forming Lower Electrode 20A and Upper Electrode 20B]

In the next step, as shown in FIG. 4B, a lower electrode 20A is formed on the rear surface 10AS1 of the semiconductor structure 10A, and an upper electrode 20B is formed on the front surface 10AS2 of the semiconductor structure 10A. The upper electrode 20B includes a light-transmitting region that is adapted to transmit the irradiation light in the DPP annealing. The transmittance of the light-transmitting region for the irradiation light can be for example equal to or higher than 60%, preferably equal to or higher than 80%. The formation of the lower electrode 20A and the upper electrode 20B can be realized by, for example, sputtering. As will be described later, when a plurality of through holes are formed as the light-transmitting region in the upper electrode 20B, patterning of the upper electrode 20B by etching can be further performed.

The lower electrode 20A and/or the upper electrode 20B can be made of at least one metal selected from the group consisting of, for example, Cu, Cr, Al, Au, Ti, Pt and Ag. Alternatively, the lower electrode 20A and/or the upper electrode 20B can be light-transmitting electrodes that are made of, for example, ITO.

The lower electrode 20A can have, for example, a flat-plate shape irrespective of whether the lower electrode 20A is made of a metal or is a light-transmitting electrode. Meanwhile, when the upper electrode 20B is made of a metal, the upper electrode 20B can have, for example, a mesh shape. The mesh shape has, for example, a plurality of through holes two-dimensionally arrayed across the front surface 10AS2. In the DPP annealing, the irradiation light can travel through the plurality of through holes and reach the front surface 10AS2 of the semiconductor structure 10A. When the upper electrode 20B is a light-transmitting electrode, the upper electrode 20B can be formed over the entirety of the front surface 10AS2 because the light-transmitting electrode itself has a light-transmitting region. As a result, the electric current can spread throughout the semiconductor structure 10A, and Joule heat can be efficiently produced. In the following description, the upper electrode 20B is made of a metal and has a mesh shape.

By forming a high-concentration impurity region in the rear surface 10AS1 of the semiconductor structure 10A, the contact resistance with the lower electrode 20A can be reduced. Likewise, by forming a high-concentration impurity region in the front surface 10AS2 of the semiconductor structure 10A, the contact resistance with the upper electrode 20B can be reduced.

[Step of Dividing]

In the next step, as shown in FIG. 4C, the wafer including the semiconductor structure 10A, the lower electrode 20A and the upper electrode 20B is divided into individual chips along a plurality of dashed lines arranged in the X direction and the Y direction. Hatched portions shown in FIG. 4C schematically represent portions of the wafer that are to be divided into individual chips. By the dividing, a chip including the semiconductor structure 10a, the lower electrode 20a and the upper electrode 20b is obtained as shown in FIG. 4D. The dividing is realized by, for example, dicing or laser scribing. The semiconductor structure 10a includes a first semiconductor region 12a that is a part of the first semiconductor region 12A and a second semiconductor region 14a that is a part of the second semiconductor region 14A. The dimensions in the X direction and the Y direction of the individual chips can each be, for example, equal to or greater than 10 μm and equal to or smaller than 5000 μm, and the dimension in the Z direction can be, for example, equal to or greater than 10 μm and equal to or smaller than 1000 μm.

[Step of DPP Annealing]

In the next step, as shown in FIG. 4E, the semiconductor structure 10a is irradiated with light 62 in the presence of a forward current flowing through the semiconductor structure 10a while the semiconductor structure 10a is in thermal contact with a cooling base 40 at a temperature higher than −40° C. and lower than 15° C., whereby the second impurity is thermally diffused. That is, the DPP annealing is performed. Thereby, the second impurity can be thermally diffused while application of the forward current facilitates radiation of the heat provided to the semiconductor structure 10a. Therefore, electrical energy is consumed by stimulated emission in which dressed photon phonons are utilized and, additionally, thermodiffusion of the second impurity advances while Joule heat is radiated by the cooling base. As a result of this step, the semiconductor structure 10 shown in FIG. 1 is obtained. That is, the second impurity is activated by the DPP annealing, and a pn junction 16 is formed at the interface between the first semiconductor region 12 and the second semiconductor region 14 in the semiconductor structure 10 as shown in FIG. 1. Because the temperature of the cooling base is relatively low, thermodiffusion and activation of the second impurity by the DPP annealing discretely advance, and a plurality of light-emitting regions 30a are formed that are discretely distributed as shown in FIG. 2. Preferably, the temperature of the cooling base 40 may be equal to or higher than −30° C. and equal to or lower than 10° C., may be equal to or higher than −25° C. and equal to or lower than 5° C., or may be equal to or higher than −25° C. and equal to or lower than −5° C. More preferably, the temperature of the cooling base 40 may be equal to or higher than −20° C. and equal to or lower than −5° C. Particularly preferably, the temperature of the cooling base 40 may be equal to or higher than −20° C. and equal to or lower than −10° C. Due to these conditions, thermodiffusion of the second impurity by the DPP annealing can advance while the cooling base 40 efficiently radiates Joule heat produced by application of the forward current.

The cooling base 40 includes, for example, a Peltier element 42 and a heat sink 44. The Peltier element 42 is located on the heat sink 44. The upper surface of the Peltier element 42 is in thermal contact with the semiconductor structure 10a via the lower electrode 20a. By allowing an electric current to flow through the Peltier element 42 in a particularly direction, the heat can be moved from the upper surface to the lower surface of the Peltier element 42. The moved heat is radiated out via the heat sink 44.

In the example shown in FIG. 4E, the first semiconductor region 12a is located closer to the cooling base 40 than the second semiconductor region 14a, and the second semiconductor region 14a is irradiated with the light 62. Due to such a configuration, the semiconductor structure 10 heated by Joule heat can be efficiently cooled, and the second impurity that is to be thermally diffused can be efficiently irradiated with the light 62.

The lower electrode 20a and the upper electrode 20b are electrically connected to a power supply 50. The power supply 50 has wires 52a, 52b. One of the wires, the wire 52a, is electrically connected to the lower electrode 20a, while the other wire 52b is electrically connected to the upper electrode 20b. The power supply 50 applies a voltage between the lower electrode 20a and the upper electrode 20b such that a stationary forward direct current can flow through the semiconductor structure 10a. The maximum of the current density can be, for example, equal to or greater than 1.0 A/cm² and equal to or smaller than 400 A/cm². When the current is caused to flow with this maximum current density and the above-described conditions of the concentration of the first and second impurities, the second impurity can be efficiently thermally diffused by Joule heat, and the heated semiconductor structure 10a can be efficiently cooled. The maximum current density is preferably equal to or greater than 10 A/cm² and equal to or smaller than 100 A/cm². This can reduce damage to the semiconductor structure 10a and/or damage to the lower electrode 20a and the upper electrode 20b and enables the second impurity to be efficiently thermally diffused by Joule heat.

While the forward current is flowing, the light source 60 emits light 62 toward the front surface 10as2 of the semiconductor structure 10a. Part of the light 62 that has passed through the light-transmitting regions of the upper electrode 20B irradiates the front surface 10as2 of the semiconductor structure 10a. The light 62 has peak energy. The peak energy is lower than the energy of the bandgap of the indirect bandgap semiconductor that is the principal material of the semiconductor structure 10a. In other words, the light 62 has a peak wavelength that is longer than a wavelength corresponding to the magnitude of the bandgap of the indirect bandgap semiconductor that is the principal material of the semiconductor structure 10a. When the principal material is silicon, the peak wavelength of the light 62 can be for example equal to or longer than 1.1 μm and equal to or shorter than 4.0 μm, preferably equal to or longer than 1.2 μm and equal to or shorter than 3.0 μm. The output density of the light 62 can be, for example, equal to or greater than 0.5 W/cm² and equal to or smaller than 100 W/cm².

The light 62 is preferably laser light. The full width at half maximum of the spectrum of the laser light is narrower than that of the spectrum of a LED, for example. Rather than using a LED as the light source of the light 62, irradiating the front surface 10as2 with laser light will realize easier control of the emission characteristics of a light source device to be manufactured. The duration of the DPP annealing can be, for example, equal to or longer than 10 minutes and equal to or shorter than 36 hours.

When the current is caused to flow, Joule heat occurs in the semiconductor structure 10a, and the second impurity is thermally diffused across the second semiconductor region 14a. By irradiation with the light 62, dressed photons and dressed photon phonons occur at the positions of the second impurity. Due to population inversion caused by the forward current, stimulated emission of light of energy corresponding to the peak energy of the light 62 occurs. Through this stimulated emission, the second impurity loses the energy. As compared with a case in which the second impurity is diffused only by heat, local cooling resulting from the energy loss caused by the stimulated emission suppresses diffusion of the second impurity. As a result, it is estimated that the second impurity forms dopant pairs, and the dopant pairs are distributed in a self-organizing manner along the interface between the first semiconductor region 12a and the second semiconductor region 14a.

When the DPP annealing is performed at room temperature, the plurality of dopant pairs are distributed throughout a part of the second semiconductor region 14a located along the interface between the first semiconductor region 12a and the second semiconductor region 14a. In contrast, when the DPP annealing is performed on the cooling base 40, Joule heat is rapidly absorbed by the cooling base 40 and, therefore, the second impurity is not sufficiently diffused in some regions. It is estimated that, at least in such regions, the amount of the formed dopant pairs of the second impurity is not sufficient for contribution to emission of light. As a result, a plurality of near-field light formation regions, each including a plurality of dopant pairs, are discretely distributed along the interface between the first semiconductor region 12a and the second semiconductor region 14a. The near-field light formation regions correspond to the light-emitting regions 30a shown in FIG. 2. When the temperature of the cooling base 40 is −40° C. or lower, the second impurity is hardly thermally diffused in the second semiconductor region 14a, and near-field light formation regions are not formed. Through the process described above with reference to FIG. 4A, FIG. 4B, FIG. 4C, FIG. 4D and FIG. 4E, the light source device 100 shown in FIG. 1 can be manufactured.

[Variations]

As shown in FIG. 4F, the wafer including the semiconductor structure 10A, the lower electrode 20A and the upper electrode 20B is placed on the cooling base 40, and the DPP annealing is performed on the wafer. Thereafter, the wafer is divided into non-classical light source devices 100. The conditions of the DPP annealing can be the same as those described above. Because the dividing is performed after the DPP annealing, the manufacture efficiency is improved. The hatching and dashed lines shown in FIG. 4F schematically represent portions of the wafer that are to be divided into individual chips. Wires 52a and 52b are connected to the area outside the portions that are to be divided into individual non-classical light source devices 100, whereby the tip ends of the wires at which the electrodes are likely to be degraded by the forward current can be selectively eliminated. As a result, the production yield improves. The cooling base 40 may include a single Peltier element 42 or may include a plurality of arrayed Peltier elements 42. The semiconductor structure 10A is shown as being in the form of a wafer in FIG. 4F but is not limited to this example.

<Applications>

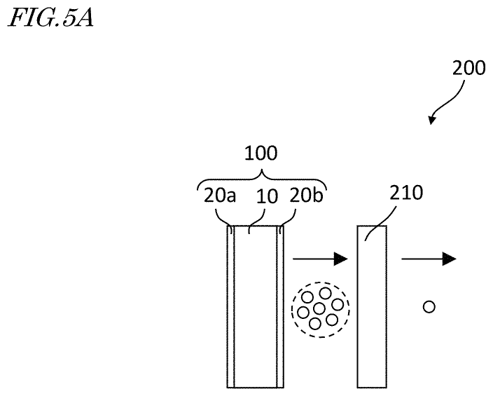

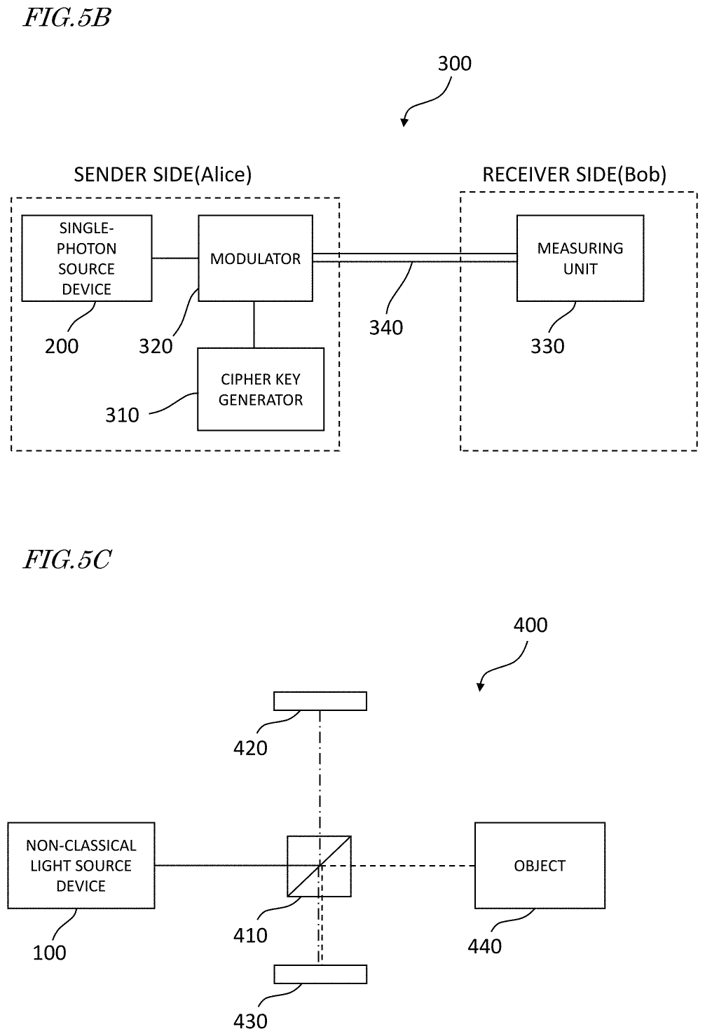

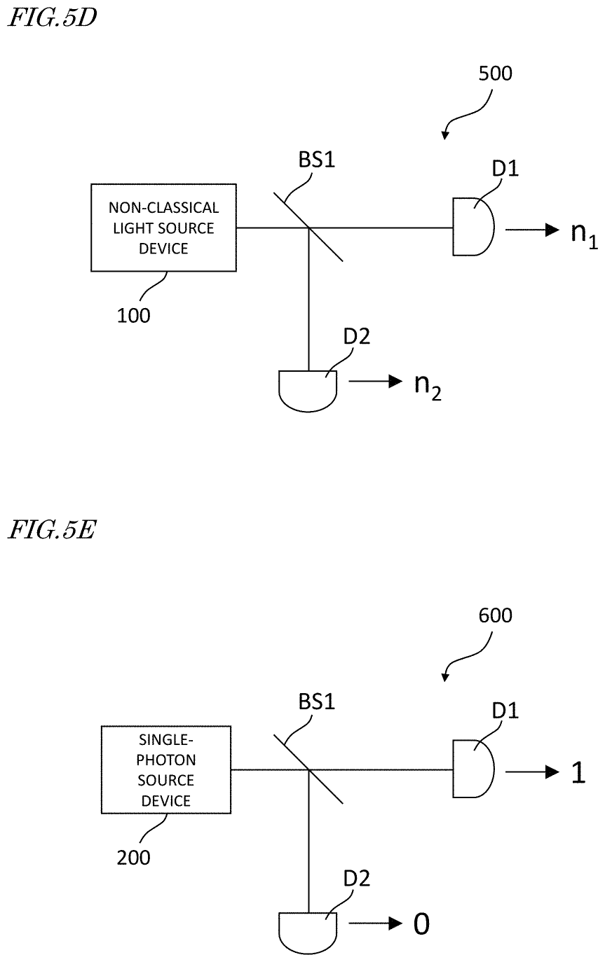

Next, an application of the light source device 100 according to the present embodiment is described with reference to FIG. 5A, FIG. 5B and FIG. 5C. For example, a single-photon source that is adapted to emit single photons can be realized using the light source device 100 according to the present embodiment. FIG. 5A is a diagram schematically showing a configuration of a single-photon source device 200 according to an example embodiment. The single-photon source device 200 shown in FIG. 5A includes the light source device 100 shown in FIG. 1 and a photon reducer 210 for reducing a plurality of photons emitted from the light source device 100 to a single photon. The photon reducer 210, for example, absorbs, reflects or scatters some of a plurality of photons emitted from the light source device 100, thereby reducing the plurality of photons to a single photon. The photon reducer 210 can be, for example, a glass plate with a layer of a metal or an oxide of the metal over a surface of the glass plate, or a glass plate with a metal or an oxide of the metal contained therein. The metal can be appropriately selected according to the wavelength of light to be reduced. For example, in reducing light that has energy corresponding to the wavelength of 1300 nm, Cr can be used. In the example shown in FIG. 5A, the photon reducer 210 is located away from the upper electrode 20b, although the photon reducer 210 may be located on the upper electrode 20b of the light source device 100. In the example shown in FIG. 5A, 6 out of 7 photons emitted from the light source device 100 are absorbed, reflected or scattered by the photon reducer 210, and a single photon goes out from the photon reducer 210. The arrows shown in FIG. 5A represent the traveling direction of the photons. Emission of a single photon can be verified by confirming that the intensity correlation function satisfies g⁽²⁾(0)<g⁽²⁾(τ) and g⁽²⁾(0)=0. Note that even if light pulses of coherent light emitted at a certain pulse frequency from a conventional mode-locked laser are reduced, a single photon cannot be obtained.

According to another application example, the single-photon source device 200 of the present embodiment may be used in a quantum cryptographic communication device. FIG. 5B is a diagram schematically showing a configuration of a quantum cryptographic communication device 300 according to an example embodiment. The quantum cryptographic communication device 300 shown in FIG. 5B includes a single-photon source device 200, a cipher key generator 310 and a modulator 320 on the information sender side (Alice), a measuring unit 330 on the information receiver side (Bob), and an optical fiber 340 extending between the information sender side and the information receiver side.

In the quantum cryptographic communication device 300, bit strings in which the quantum state of a single photon represents one bit are used for exchanging cipher keys. On the information sender side, the cipher key generator 310 generates a cipher key, and the modulator 320 modulates the quantum state of each of single photons in a single-photon sequence emitted from the single-photon source device 200 based on the cipher key. The optical fiber 340 distributes single-photon sequences that have information of cipher keys. On the information receiver side, the measuring unit 330 measures the single-photon sequences that have information of cipher keys.

Exchange of information as described above is called quantum key distribution, which enables communications that are difficult to eavesdrop on. In sending bit strings from a sender to a receiver where the quantum state of a plurality of photons, rather than a single photon, represents one bit, even if a third party takes out some of the plurality of photons, the receiver will not notice the eavesdropping because the remaining photons reach the receiver. In contrast, in sending bit strings in which the quantum state of a single photon represents one bit, if a third party takes out a photon, the receiver can notice the eavesdropping because the photon does not reach the receiver. It can be considered that the third party may measure the taken photon and send the measured photon to the receiver in order to prevent the receiver from noticing the eavesdropping. However, because the quantum state of the photon changes due to the measurement, the third party cannot send the photon in the original quantum state to the receiver. It can also be considered that the third party may not measure but may replicate the taken photon and send the taken photon as it is to the receiver. However, such replication is impossible because of such a non-cloning theorem that an unknown quantum state cannot be replicated. The quantum key distribution that utilizes bit strings in which the quantum state of a single photon represents one bit as keys for encryption or decryption of information can realize communications that are difficult to eavesdrop on. In this specification, the quantum cryptographic communication is not limited to the quantum key distribution but means a communication technology that utilizes the properties of quantum mechanics to improve the secrecy of communication.

According to still another application example, the non-classical light source device 100 of the present embodiment may be used as a light source of an optical coherence tomograph (Optical Coherence Tomography). Optical coherence tomographs have been used in diagnosis based on images of the retinal tissue of the eye fundus and the eyes and their surrounding tissues, and are expected to be applied to diagnosis of superficial tissues of the gastrointestinal tract and the trachea. Non-classical light emitted from the non-classical light source device 100 has a characteristic such that the photon number fluctuation is small as compared with classical light and, therefore, the noise in interferometric measurement can be reduced.

FIG. 5C is a diagram schematically showing a configuration of an optical coherence tomograph 400 according to an example embodiment. The optical coherence tomograph 400 shown in FIG. 5C includes a non-classical light source device 100, a beam splitter 410, a reference mirror 420, and a sensor 430. FIG. 5C also shows an object 440. The beam splitter 410 transmits part of light emitted from the non-classical light source device 100 so as to travel toward the object 440 and reflects the remaining part so as to travel toward the reference mirror 420. The beam splitter 410 reflects the reflection (return light) from the object 440 so as to travel toward the sensor 430 and transmits the reflection (return light) from the reference mirror 420 so as to travel toward the sensor 430. The sensor 430 senses superposed light where the reflection (return light) from the object 440 and the reflection (return light) from the reference mirror 420 interfere with each other. Because the light emitted from the non-classical light source device 100 has a small photon number fluctuation, it is possible to more accurately measure cross sections of the object 440 by optical interference with small noise.

The non-classical light source device 100 and the single-photon source device 200 according to the present embodiment can also be used in a random number generator. FIG. 5D is a diagram schematically showing a configuration of a random number generator 500 according to an example embodiment. The random number generator 500 shown in FIG. 5D includes a non-classical light source device 100, a beam splitter BS1 adapted to transmit and/or reflect a photon emitted from the non-classical light source device 100 so as to travel along at least one of two routes, a detector D1 for detecting a photon traveling along one of the routes, and a detector D2 for detecting a photon traveling along the other route. A plurality of photons emitted from the non-classical light source are transmitted through and/or reflected by the beam splitter BS1 so as to travel along at least one of the routes. Because at least one photon is emitted from the non-classical light source device 100, one or more photons are detected by at least either of the detector D1 or the detector D2. FIG. 5D illustrates detection of n₁ photons by the detector D1 and detection of n₂ photons by the detector D2. The number of photons split by the beam splitter is random and, thus, the configuration shown in FIG. 5D can generate random numbers. The non-classical light source device 100 can emit photons at a pulse frequency equal to or higher than 100 MHz and equal to or lower than 10 GHz and therefore can generate random numbers at high speed. In the non-classical light source device 100, the emission timings of photons from the light-emitting regions 30a are independent of one another and, therefore, the randomness of random numbers can be improved.

FIG. 5E is a diagram schematically showing another configuration of a random number generator 600 according to an example embodiment. The random number generator 600 shown in FIG. 5E is different from the random number generator 500 shown in FIG. 5D in that the light source is the single-photon source device 200. The single-photon source device 200 can have the configuration such as shown in FIG. 5A. In the random number generator 600, the beam splitter BS1 transmits or reflects a single photon emitted from the single-photon source device 200 so as to travel along at least one of two routes. Any one of the detector D1 and the detector D2 detects the single photon. That is, using the random number generator 600 such as shown in FIG. 5E enables generation of binary random numbers. FIG. 5E illustrates a case in which the detector D1 detects one single photon while the detector D2 does not detect a single photon. In the random number generators shown in FIG. 5D and FIG. 5E, one or more sets of a beam splitter and a detector may be further provided in at least one of the routes after transmission through or reflection by the beam splitter BS1, so that more complicated random numbers can be generated.

According to an application example other than those described above, the number of photons emitted from the non-classical light source device 100 of the present embodiment may be changed by a photon reducer such that information can be transmitted based on the number of photons. This can be utilized in, for example, a quantum computer that uses light.

### Example 1

Next, Example 1 of the non-classical light source device 100 of the present embodiment is described. Hereinafter, the non-classical light source device 100 is simply referred to as light source device 100. The light source device according to Example 1 was manufactured through the process described with reference to FIG. 4A, FIG. 4B, FIG. 4C, FIG. 4D and FIG. 4E. In the example shown in FIG. 4A, the semiconductor structure 10A was formed by ion-implanting B atom twice in a surface of a n-type silicon substrate that has Sb atom as the n-type impurity. The electrical resistivity of the n-type silicon substrate was 5 Ωcm. The first ion implantation was performed at the dose of 2.7×10¹⁴/cm² and the energy of 700 keV such that B atoms can be distributed inside the n-type silicon substrate. The second ion implantation was performed at the dose of 5.3×10¹⁴/cm² and the energy of 10 keV such that B atoms can be distributed near the surface of the n-type silicon substrate. As a result, the peak concentration of B atoms was 1.0×10¹⁸ cm⁻³ at the depth of 1.5 μm from the surface and 5.0×10¹⁹ cm⁻³ at the depth of 50 nm from the surface.

In the example shown in FIG. 4C, the dividing was realized by dicing with a diamond blade. In the example shown in FIG. 4E, the temperature of the cooling base in the DPP annealing was −15° C. The irradiation laser light was continuous wave laser light at the wavelength of 1.31 μm and the power of 10 W/cm². The forward current was a stationary direct current, and the maximum current value was 600 mA. The duration of the DPP annealing was 3 hours.

The thus-manufactured light source device of Example 1 had the configuration shown in FIG. 1. The dimensions in the X direction and the Y direction of the light source device of Example 1 were each 1 mm, and the dimension in the Z direction was 150 μm. In the semiconductor structure 10, the dimension in the Z direction of the second semiconductor region 14 was 2 μm. The lower electrode 20a had a multilayer structure of Cr/Al/Au layers from the semiconductor structure 10 side, and the thicknesses of the Cr, Al and Au layers were 30 nm, 200 nm and 300 nm, respectively. The upper electrode 20b had a mesh shape and had a multilayer structure of Cr/Au layers from the semiconductor structure 10 side. The thicknesses of the Cr and Au layers were 30 nm and 200 nm, respectively.

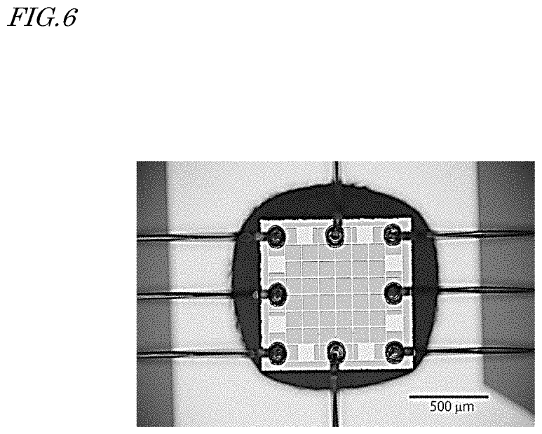

FIG. 6 is a photographic image of the upper surface of a light source device of Example 1. The upper electrode in a mesh shape was provided on the front surface of the semiconductor structure. The upper and lower sides of the upper electrode were each electrically connected to a single wire, and the left and right sides were each electrically connected to three wires. The lower electrode was provided on the rear surface of the semiconductor structure. The lower electrode was electrically connected to the interconnection of a ceramic circuit board of AlN that had high thermal conductivity.

### Comparative Example 1

The light source device of Comparative Example 1 was manufactured under the same conditions as those of Example 1 except that the temperature of the cooling base in the DPP annealing was 20° C.

### Comparative Example 2

The light source device of Comparative Example 2 was manufactured under the same conditions as those of Example 1 except that the temperature of the cooling base in the DPP annealing was −40° C.

### Experimental Results

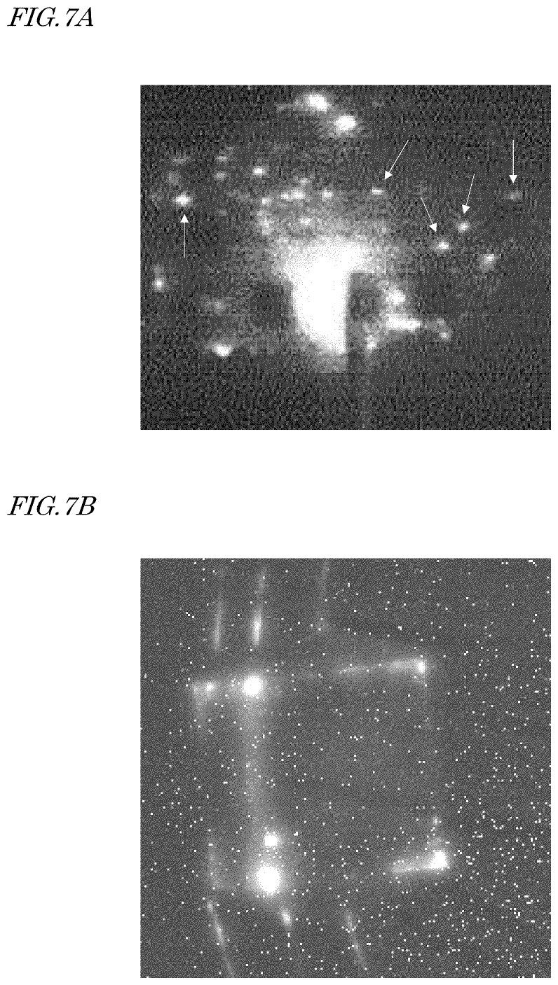

Next, the results of imaging of emission of light from the light source devices of Example 1 and Comparative Example 1 are described with reference to FIG. 7A and FIG. 7B. When a stationary DC voltage of 42 V was applied to the light source device of Example 1, emission of light was confirmed. When a stationary DC voltage of 40 V was applied to the light source device of Comparative Example 1, emission of light was confirmed. Because infrared light was emitted from the light source devices of Example 1 and Comparative Example 1, an infrared camera was used in this imaging. The spatial resolution of the infrared camera was 10 μm. The frame rate of the infrared camera was 16.7 milliseconds.

FIG. 7A is a photographic image showing emission of light from the light source device of Example 1. FIG. 7A is an enlarged image of some of the portions in which emission of light was confirmed. FIG. 7B is a photographic image showing emission of light from the light source device of Comparative Example 1. As the portions in which emission of light was confirmed, the light source device of Example 1 produced a plurality of discretely-distributed light-emitting regions as shown in FIG. 7A. White arrows shown in FIG. 7A represent some of the plurality of light-emitting regions. The area of each of the light-emitting regions shown in FIG. 7A was equal to or smaller than 25 μm². Two adjacent light-emitting regions were observed as being separated from each other. The shortest distance between two adjacent light-emitting regions was equal to or greater than 50 μm. It was confirmed that, by applying a stationary DC voltage, each of the light-emitting regions repeatedly flickered. In contrast, as shown in FIG. 7B, with the light source device of Comparative Example 1, a plurality of discretely-distributed light-emitting regions were not confirmed. In the light source device of Comparative Example 1, the entire surface constantly emitted light, and the emission intensity was higher at the periphery than in the central area. Because the resolution of the infrared camera is 10 μm, even if there are a plurality of discretely-distributed light-emitting regions, the gap between two adjacent light-emitting regions is smaller than 10 μm. White spots seen across the entire surface of FIG. 7B are noise of the camera and are not the light-emitting regions of the light source device. In Comparative Example 2, observation of emission was performed in the same way, but neither a plurality of discretely-distributed light-emitting regions nor a light-emitting region with emission across the entire surface was observed. It is estimated that, in Comparative Example 2, a near-field light formation region was rarely formed.

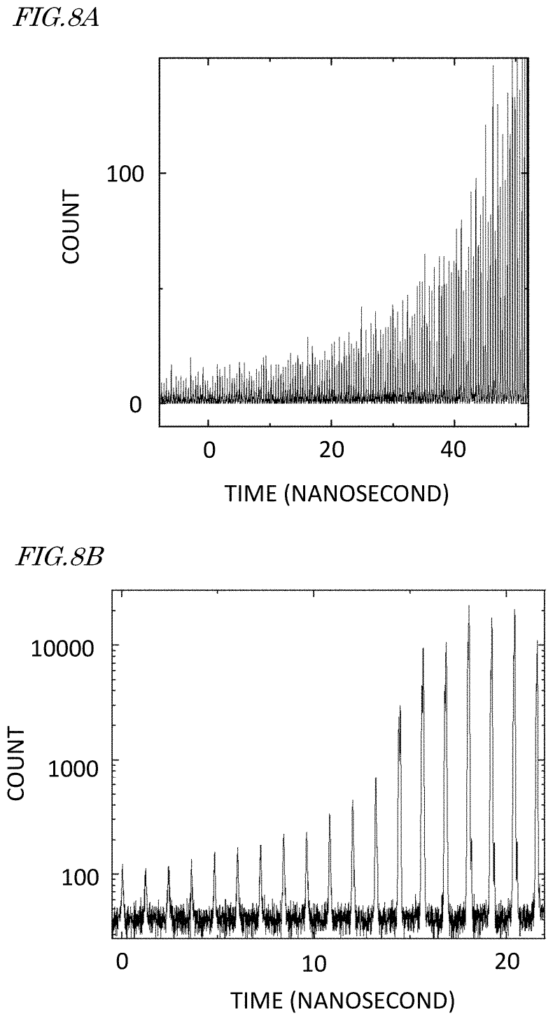

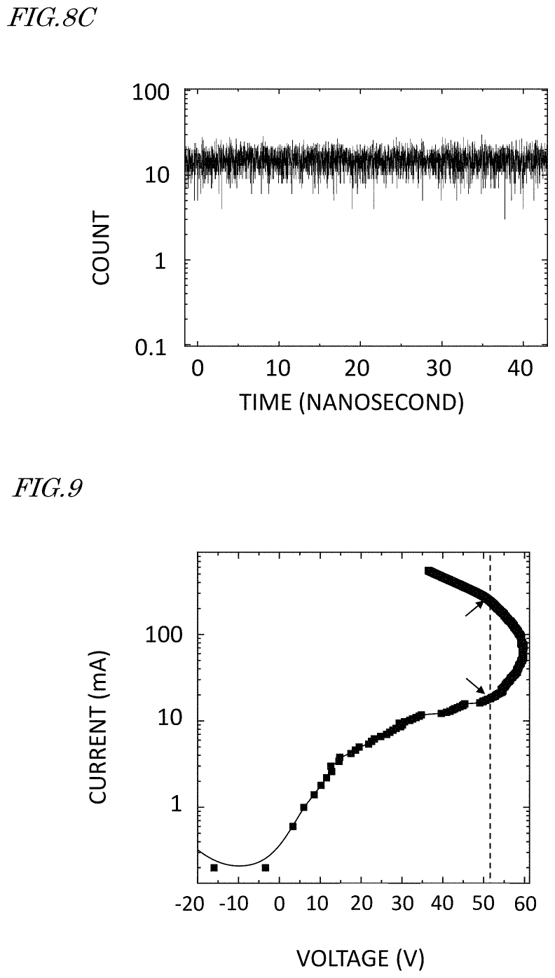

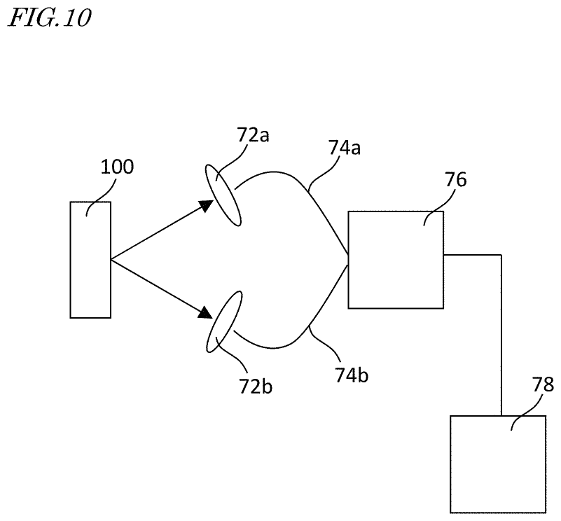

Next, the results of measurement of the intensity correlation function of light emitted from the light source devices of Example 1 and Comparative Example 1 are described with reference to FIG. 8A, FIG. 8B and FIG. 8C. This measurement was carried out based on a Hanbury Brown-Twiss experimental system shown in FIG. 10. Details of FIG. 10 will be described later. Part of light emitted from the light source devices of Example 1 and Comparative Example 1 was detected by a superconducting single photon detector 76 via an optical fiber. The superconducting single photon detector 76 is adapted to detect single photons of infrared light with high sensitivity. The time resolution in measurement was 50 picoseconds.

FIG. 8A is a graph showing the relationship between the intensity of light emitted from the light source device of Example 1 and the time. The intensity of light is represented by the photon count value. As seen from FIG. 8A, light pulses including a plurality of photons were emitted, and the peak intensity of the light pulses generally monotonically increased over time in the time range from 0 nanosecond to 50 nanoseconds. In the example shown in FIG. 8A, the pulse frequencies of the light pulses emitted from the plurality of light-emitting regions can be different from one another, and therefore, it is estimated that light pulses of different pulse frequencies coexist.

FIG. 8B is a graph showing the relationship between the intensity of light emitted with periods of 1.1 nanoseconds (pulse frequency: 900 MHz) from the light source device of Example 1 and the time. As seen from FIG. 8B, one of a plurality of light-emitting regions emitted light pulses at the pulse frequency of 900 MHz.

Further, by measuring the intensity of light with varying periods at a predetermined cumulative time, it can be confirmed that the intensities of light emitted from at least two light-emitting regions are different from each other. In this way, as well as the example shown in FIG. 8B, light at the pulse frequency of 800 MHz and light at the pulse frequency of 2 GHz were confirmed. That is, it was suggested that the pulse frequencies in at least two of the plurality of light-emitting regions can be different from each other.

FIG. 8C is a graph showing the relationship between the intensity of light emitted from the light source device of Comparative Example 1 and the time. As shown in FIG. 8C, in the light source device of Comparative Example 1, light of generally constant intensity was constantly measured. On the other hand, light pulses were not measured.

Next, the current-voltage characteristic of a semiconductor structure of Example 1 is described with reference to FIG. 9. FIG. 9 is a graph showing the current-voltage characteristic of the semiconductor structure of Example 1. The current-voltage characteristic was obtained by measuring the voltage difference between the lower electrode and upper electrode, which was caused by injecting an electric current of a constant value. The semiconductor structure exhibited such negative resistance that, as the current I increased, the voltage V monotonically increased and thereafter monotonically decreased. As seen from FIG. 9, when the voltage was equal to or higher than 0 V and lower than 35 V, the current I exhibited a single value. When the voltage V was equal to or higher than 35 V and equal to or lower than 60 V, the current I exhibited two values. It was estimated that, when the applied voltage was for example 50 V (see dashed line), the light source device was periodically driven due to the relaxation oscillation where the current I alternated between two values (see arrows), and light pulses were emitted at a certain pulse frequency from each of the light-emitting regions.

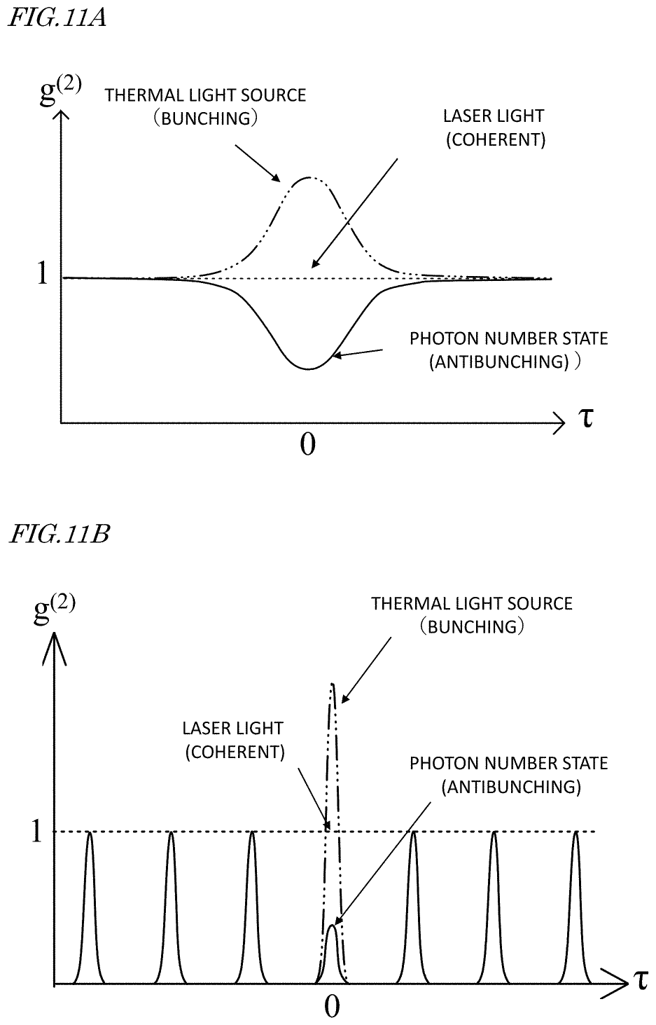

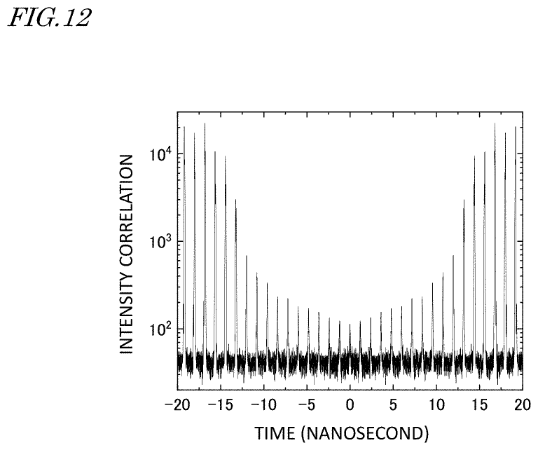

Next, we explain with reference to FIG. 10, FIG. 11 and FIG. 12 that the light emitted from the light source device of Example 1 is non-classical light. FIG. 10 is a diagram schematically showing a Hanbury Brown-Twiss experimental system for measurement of the intensity correlation function g⁽²⁾(τ). The experimental system shown in FIG. 10 includes the light source device 100 of Example 1, lenses 72a and 72b, an optical fiber 74a for transmitting photons collected by the lens 72a, an optical fiber 74b for transmitting photons collected by the lens 72b, a superconducting single photon detector 76, and a time correlation measuring unit 78. The superconducting single photon detector 76 of FIG. 10 is capable of 4ch mounting, and a single unit of the superconducting single photon detector can separately detect the photons transmitted through the optical fiber 74a and the photons transmitted through the optical fiber 74b. In this experiment, the lenses and optical fibers were used, instead of a beam splitter, to divide a plurality of photons emitted from the light source device 100 such that some photons traveled along the route of the lens 72a and the optical fiber 74a while the other photons traveled along the route of the lens 72b and the optical fiber 74b. The photons traveling along each of the routes were detected by a single unit of the superconducting single photon detector 76. The superconducting single photon detector 76 output a signal according to the number of detected photons. The time correlation measuring unit 78 output the time correlation of the signal output from the superconducting single photon detector 76. The intensity correlation function g⁽²⁾(τ) is the time integral of the product of light intensities that are different in time by τ for light traveling along the two routes (i.e., time correlation). τ represents shifting the intensities of light in the two routes by time τ.

Whether the light is classical light or non-classical light can be determined by examining the intensity correlation function g⁽²⁾(τ). This is specifically described with reference to FIG. 11A and FIG. 113. FIG. 11A and FIG. 113 are graphs schematically showing the behavior of an ideal intensity correlation function g⁽²⁾(τ) of classical light (e.g., thermal light source and laser light) and non-classical light (e.g., photon number state). FIG. 11A shows the time correlation in the case of a continuous wave. FIG. 113 shows the time correlation in the case of periodical light pulses. When the light is treated as a classical electromagnetic wave as in the case of thermal light sources, the intensity correlation function g⁽²⁾(τ) satisfies the relationship of g⁽²⁾(0)>g⁽²⁾(τ) (τ≠0) as represented by the three-dot chain line in FIG. 11A and FIG. 113. This represents bunching of photons. When the light is coherent as laser light is, the intensity correlation function g⁽²⁾(τ) satisfies the relationship of g⁽²⁾(0)=g⁽²⁾(τ) as represented by the dashed line in FIG. 11A and FIG. 113. Note that g⁽²⁾(τ) of the laser light shown in FIG. 113 represents a discrete time correlation whose value is 1. In contrast, when the light is in a non-classical state, the intensity correlation function g⁽²⁾(τ) satisfies the relationship of g⁽²⁾(0)<g⁽²⁾ (τ) (τ≠0) as represented by the solid line in FIG. 11A and FIG. 113. This represents antibunching of photons. Thus, whether or not the light is in a non-classical state can be determined by confirming whether or not the intensity correlation function g⁽²⁾ exhibits the behavior of g⁽²⁾(0)<g⁽²⁾(τ) (τ≠0). Note that, in the examples shown in FIG. 11A and FIG. 11B, the function is normalized to g⁽²⁾(τ)=1 at |τ|→^{∞}. When the bunching behavior and the antibunching behavior of photons are qualitatively confirmed, it is not necessary to normalize the function. That is, the relationship in largeness between the intensity correlation function for τ=0 and the intensity correlation function for τ≠0 measured in the Hanbury Brown-Twiss experimental system may be examined.

FIG. 12 is a graph of the intensity correlation function of light emitted with periods of 1.1 nanoseconds (pulse frequency: 900 MHz) from the light source device 100 of Example 1. As shown in FIG. 12, the intensity correlation function satisfied the relationship of g⁽²⁾(0)<g⁽²⁾(τ) and exhibited antibunching of photons. If the light is classical light, g⁽²⁾(0)>g⁽²⁾(τ) holds. Therefore, it is understood that the light emitted from the light source device 100 of Example 1 is non-classical light. Further, because g⁽²⁾(0)>0 holds, it is estimated that the non-classical light is in a photon number state where the photon number is 2 or more, in a state where a plurality of single photons have been produced, or in a non-classical state similar to such states.

A non-classical light source device of the present disclosure is applicable to, for example, devices that utilize the particle nature of light.

What is claimed is:

1. A method of manufacturing a non-classical light source device, the method comprising:
providing a semiconductor structure that comprises:
a first semiconductor region having a first impurity of a first conductivity type that is one of p-type or n-type, and
a second semiconductor region having a second impurity of a second conductivity type that is the other of p-type or n-type; and
irradiating the semiconductor structure with light in the presence of a forward current flowing through the semiconductor structure while the semiconductor structure is in thermal contact with a cooling base at a temperature higher than −40° C. and lower than 15° C., thereby diffusing the second impurity.

2. The method of claim 1, wherein:
the first semiconductor region is closer to the cooling base than is the second semiconductor region; and
the second semiconductor region is irradiated with the light.

3. The method of claim 1, wherein:
a concentration of the first impurity is equal to or higher than 1.0×10¹⁴ cm⁻³ and equal to or lower than 1.0×10²⁰ cm⁻³,
a concentration of the second impurity is equal to or higher than 1.0×10¹⁸ cm⁻³ and equal to or lower than 1.0×10²⁰ cm⁻³, and
a maximum of a current density of the forward current is equal to or higher than 1.0 A/cm² and equal to or lower than 400 A/cm².

4. The method of claim 1, wherein:
a principal material of the semiconductor structure is an indirect bandgap semiconductor; and
the light has a peak wavelength that is longer than a wavelength corresponding to a magnitude of a bandgap of the indirect bandgap semiconductor.

5. A non-classical light source device, comprising:
a semiconductor structure that comprises:
a first semiconductor region having a conductivity type that is one of p-type or n-type,
a second semiconductor region having a conductivity type that is the other of p-type or n-type,
a pn junction located between the first semiconductor region and the second semiconductor region, and
a plurality of light-emitting regions discretely distributed along the pn junction, each of the light-emitting regions being adapted to emit non-classical light; and
an electrode structure configured to apply a voltage to the pn junction; wherein:
a principal material of the first semiconductor region and the second semiconductor region is an indirect bandgap semiconductor; and
as viewed using a camera with a spatial resolution of 10 μm at a predetermined frame rate in a direction perpendicular to the pn junction, portions of light respectively emitted from the plurality of light-emitting regions are observed as being separated from one another.

6. The non-classical light source device of claim 5, wherein the semiconductor structure has negative resistance.

7. The non-classical light source device of claim 5, wherein, as viewed in a direction perpendicular to the pn junction, between at least two of the plurality of light-emitting regions, an emission intensity at a predetermined cumulative time is different.

8. The non-classical light source device of claim 5, wherein, as viewed in a direction perpendicular to the pn junction, an area of the plurality of light-emitting regions is equal to or smaller than 25 μm².

9. The non-classical light source device of claim 5, wherein:
an energy of each of a plurality of photons of the non-classical light is lower than an energy of a bandgap of the indirect bandgap semiconductor.

10. A single-photon source device, comprising:
the non-classical light source device according to claim 5; and
a photon reducer adapted to reduce a plurality of photons emitted from the non-classical light source device to a single photon.

11. A random number generator, comprising:
the single-photon source device according to claim 10;
a beam splitter configured to transmit and/or reflect a photon emitted from the single-photon source device so as to travel along at least one of two routes;
a first detector configured to detect a photon traveling along a first of the routes; and
a second detector configured to detect a photon traveling along a second of the routes.

12. A random number generator, comprising:
the non-classical light source device according to claim 5;
a beam splitter configured to transmit and/or reflect a photon emitted from the non-classical light source device so as to travel along at least one of two routes;
a first detector configured to detect a photon traveling along a first of the routes; and
a second detector configured to detect a photon traveling along a second of the routes.
